(19) United States
(12) Patent Application Publication
(10) Pub. No.: US 2010/0276173 A1
(43) Pub. Date: Nov. 4, 2010

(54) DOUBLE-WALL HOUSING HAVING IMPROVED HEAT-REMOVING FUNCTION CHAMBER WALLS

(75) Inventors: Oliver Birkenstock, Berlin (DE); Wolfgang Kraft, Berlin (DE)

Correspondence Address: MERCHANT & GOULD PC, P.O. BOX 2903, MINNEAPOLIS, MN, 55402-0903, US

(73) Assignee: ADC GMBH

(21) Appl. No.: 12/746,493

(22) PCT Filed: Nov. 26, 2008
(86) PCT No.: PCT/EP08/10010

§ 371 Date: Jun. 4, 2010

(30) Foreign Application Priority Data
Dec. 4, 2007 (DE) 10 2007 058 458.1

(51) Int. Cl. H05K 5/06

(52) U.S. Cl. 174/50.5

(57) ABSTRACT

The invention relates to a housing (1) for installation in the open air in order to accommodate electrical devices, in particular components for communication and/or data technology, having an inner housing (2) in which a hermetically sealed functional area is provided for accommodation of the electrical devices, and an outer housing (3), which is arranged around the inner housing (2) in such a way that a cavity (4) is formed between the inner housing (2) and the outer housing (3), with side walls (6) of the inner housing (2) also being the side walls (6) of the functional area, wherein the side walls (6) of the inner housing (2) are metal sheets (20), with at least one of the metal sheets (20) being shaped with structuring (13) such that the area in the region of the structuring (13) is greater than that of a smooth surface.

The invention relates to a housing as claimed in the preamble of patent claim 1.

Housings or cabinets for accommodating electrical devices, in particular components for communication and/or data technology, are known from the prior art and are intended to be installed outdoors, that is to say in the open air. Electrical devices, in particular electronic circuits and appliances, are arranged in a functional area, which is designed to be dust-tight and water-tight, that is to say it is hermetically sealed. Active electrical devices produce heat losses while they are being operated. These must be dissipated from the functional area in order to prevent overheating of the electrical devices in the functional area.

DE 198 12 117 A1 discloses an equipment cabinet for electrical and electronic appliances and components, having a functional area which is surrounded by a multi-shell wall and at least one door and is sealed to be dust-tight and water-tight. One functional-area wall is arranged between an outer wall and a baffle wall on the inside, and is provided with ribs in order to ensure particularly good heat dissipation from the functional area. The ribs are in the form of rib rails, which are provided with a multiplicity of rib elements and aperture openings. The rib rails are attached to the functional-area walls.

DE 101 19 095 A1 discloses a switchgear cabinet for electrical and electronic appliances, which is sealed to be dust-tight and water-tight and, at least in places, has a multi-shell wall and emits heat that is created in the interior through the housing wall to the exterior and offers adequate protection for the electrical and electronic appliances, so that it can be installed in the open air. Thermally conductive bodies of a simple shape are provided there and are fitted in a thermally conductive form to the wall of the functional area.

Although the known housings are able to ensure that heat is dissipated from the interior of the functional areas, the manufacturing effort for the housings is, however, very great.

The invention is therefore based on the technical object of providing a housing of the type mentioned initially, which can be produced easily and at low cost and allows better dissipation of heat from the interior of a hermetically sealed functional area.

According to the invention, the object is achieved by a housing having the features of patent claim 1. Advantageous refinements are specified in the dependent claims.

A housing is provided for installation in the open air in order to accommodate electrical devices, in particular components for communication and/or data technology, which has: an inner housing in which a hermetically sealed functional area is provided for accommodation of the electrical devices, and an outer housing, which is arranged around the inner housing in such a way that a cavity is formed between the inner housing and the outer housing, with side walls of the inner housing also being the side walls of the functional area, wherein the side walls of the inner housing are metal sheets, with at least one of the metal sheets being shaped with structuring such that the area in the region of the structuring is greater than that of a smooth, flat surface. It is considerably simpler to shape a metal sheet with structuring than to fit heat sinks, rib rails or thermally conductive bodies. Increasing the surface area such that it is greater than that of a smooth, flat surface of a conventional metal sheet leads to an increase in the amount of heat dissipated. The current flowing through the electrical devices in this case produces heat losses which in general are dissipated from the electrical devices by fluid circulation, generally air circulation in the interior of the functional area, which is hermetically sealed. The air flow passes over the boundary walls or is deliberately passed via active elements (for example fans) and/or passive elements (for example guide plates) to them. In this case, heat from the fluid is transferred to the walls of the internal area bounding the functional area, that is to say, inter alia, to the side walls. The side walls can also be partially directly heated by thermal radiation emitted from the electrical devices. The heated side walls of the functional area, which are the side walls of the inner housing and are formed from thermally conductive metal sheets, carry the heat to a surface of the side wall facing a cavity. The cavity is formed between the inner housing and an outer housing. This cavity likewise contains a fluid, generally air. The greater the heated surface area of the side wall, the better heat can be dissipated to the fluid located in the cavity. This fluid is heated. This results in a convection flow, essentially vertically from the bottom upward. Alternatively or additionally, an active element, for example a fan, may be provided in order to assist or to start a fluid flow in the cavity. The outer housing is generally designed such that fluid heated in the cavity, air, can emerge in the roof area of the outer housing and, at the same time, colder fluid, which has not yet been heated, can enter the cavity in a lower area of the outer housing. If an active element is used, then it is also possible to produce a flow in the opposite direction to that described.

The structuring is advantageously designed such that channels which run in straight lines are formed both on the side facing the functional area and on the side facing the cavity. This allows and promotes a flow both along the inner surface of the side wall of the functional area and along one of the faces of the side wall, facing the cavity. Cooling down the heated fluid on the side metal sheets in the interior of the functional area results in a flow in the downward direction in the straight-line channels on the side facing the functional area. In contrast, the convection flow that has already been mentioned above occurs on the side facing the cavity, unless any active elements (fans, etc.) are used for cooling.

This flow is formed particularly well if the channels are aligned in straight lines at an angle of less than 45° to a vertical, preferably parallel to the vertical.

In principle, structures can be formed on a metal sheet in various ways. In order to allow the individual side walls, which are preferably attached by attachment elements to a frame, manufactured from profiles, for the inner housing, to be handled easily, in particular to be transported and stored easily, the metal sheets are preferably structured such that the metal sheets can be stacked, with the stacking height during a stacking process being increased essentially only by the sheet thickness of the metal sheet. This means that the structuring is shaped such that it engages in the structuring of the metal sheet arranged underneath it during stacking, or vice versa. The faces of the metal sheet are therefore shaped to be mutually complementary.

In one preferred embodiment, the structuring is shaped such that a section line of the structuring forms a periodic contour with a plane at right angles to the straight-line profile of the channels. The channels are therefore shaped identically, preferably repetitively.

The periodic contour preferably has a rectangular, triangular, trapezoidal, corrugated or sinusoidal shape, or a shape similar to a sinusoid. The straight-line channels are formed alternately towards the interior of the functional area and toward the interior of the cavity. The cross-sectional areas resulting from this and/or shapes of the channels that are formed in the interior of the functional area and in the interior of the cavity between the inner housing and the outer housing are preferably essentially identical. There may be discrepancies at the ends of the channels, in particular in order to hermetically seal the functional area.

It has been found to be particularly advantageous for the ratio of the period length of the contour or structuring to the structure depth to be between 3 to 1 (60/20) and 1 to 4 (10/40), preferably between 2 to 1 and 2 to 3. Structures in which the ratio of the period length to the structure depth is 1 to 1 have been found to be particularly suitable. In this case, with sinusoidal or corrugated structuring, channels are formed in which the ratio between the maximum channel width and the channel depth is 1 to 1. In the case of sinusoidal structuring, the ratio of the width at half the depth to the depth at half the channel depth is 1 to 2. Different embodiments may provide for this ratio to have a value of 1 to 3. In general, it is advantageous in this case for the structuring to be formed such that, in the case of the resultant straight-line channels, at least the mutually adjacent channels, one of which is open toward the functional area and the other is open toward the cavity between the inner housing and the outer housing, but preferably all the channels, have an identical structure depth and/or channel depth and/or structure width and/or channel width. In particular, a sinusoidal and/or corrugated structure generally has these characteristics.

The structuring is preferably formed in the metal sheets by deep-drawing or stamping. Bending and pressing can likewise be used. Furthermore, roller profiling is possible.

The minimum distance between the side wall of the inner housing and the outer wall of the outer housing, that is to say the minimum distance between the surfaces of the side wall facing the cavity and the outer wall, is dependent on the fluid flow rate through the cavity in the region of the structuring. If there are no active elements, for example fans which are used to assist or maintain a fluid flow, then the minimum distance may be chosen to be less than if active elements such as these are used, resulting in a high fluid flow rate. If no heat is introduced into the housing as a result of thermal radiation (for example solar radiation), or there is no need to be concerned about this, then the minimum distance can be reduced to zero provided that no active elements are used and the fluid flow in the cavity between the inner housing and the outer housing is driven only by convection. In a situation such as this, thermal conduction at the contact points is advantageous. In general, however, the minimum distance between the surfaces of the outer wall facing the cavity and the side wall is not equal to zero, that is to say it is greater than zero, in order to ensure insulation of the inner housing against radiated heat striking the outer housing.

To a person skilled in the art, it is self-evident that one of the side walls or a portion of one of the side walls of the functional area may be in the form of a door. The door surface is also preferably formed by a metal sheet which is structured in the manner stated above.

The metal sheets are preferably aluminum, copper, iron or steel sheets, or sheets composed of metal alloys.

The invention will be explained in more detail in the following text with reference to the drawing, in which:

FIG. 1 shows a schematic view of a housing with a rear wall of an outer housing having been removed.

FIG. 2 shows a schematic side view of the housing shown in FIG. 1, in which one side wall of the outer housing has been removed.

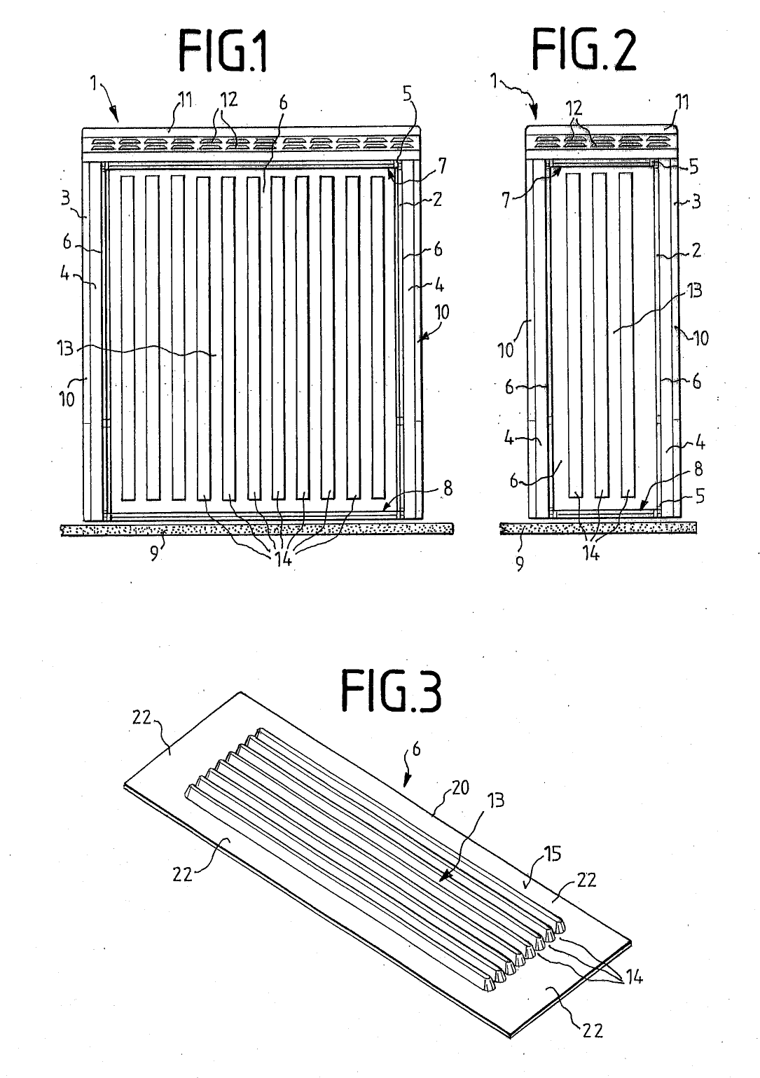

FIG. 3 shows an isometric view of one embodiment of a side wall of the inner housing, which has been shaped with structuring.

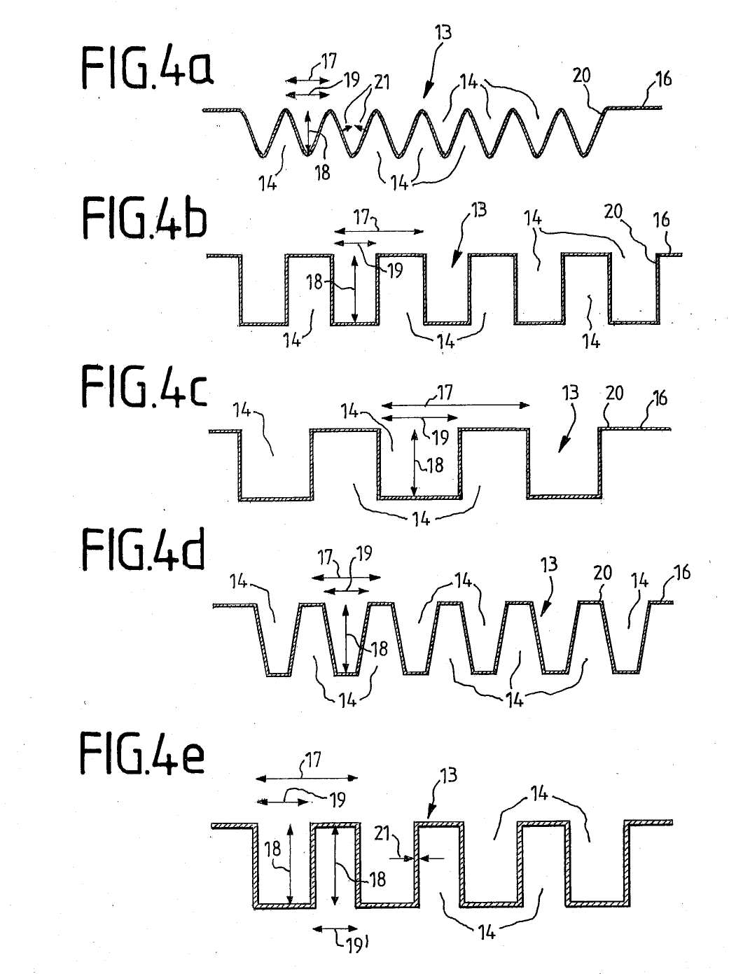

FIGS. 4a to 4e show contours of different structures, in the form of section lines of the structuring on a plane at right angles to a straight-line profile of channels that are formed by the structuring.

FIG. 1 shows a schematic view of a housing 1 from the rear, which is intended for installation in the open air, that is to say outdoors. FIG. 2 shows the corresponding housing 1 from one side. The housing 1 has an inner housing 2, which is surrounded by an outer housing 3. The outer housing 3 surrounds the inner housing 2 and is arranged such that a cavity 4 is formed between the inner housing 2 and the outer housing 3. To a person skilled in the art, it is self-evident that a plurality of cavities 4 may be formed, which are preferably connected to one another for flow purposes.

The inner housing 2 preferably comprises a frame 5 which is formed from profiles and to which the side walls 6 are attached by attachment elements, such as those with which a person skilled in the art will be familiar, for example by screwing or by means of clamping strips or clamps. The side walls 6 surround a functional area in the interior of the inner housing, which is hermetically sealed, to be dust-tight and water-tight, by the side walls 6 at the sides, by a top 7 at the top, and by a bottom 8 at the bottom. The bottom generally comprises sealed bushings in order to pass electrical, and possibly additionally optical, cables into the functional area. Electrical devices, in particular electronic components for communication and/or data technology, are installed in the interior of the functional area. The functional area need not extend over the entire height of the side walls 6. In fact, a bottom 8 can be arranged above the level of the ground 9.

The outer housing 3 comprises outer walls 10 and a roof 11. The outer walls 10 and the roof 11 are preferably likewise attached to the frame 5. The outer walls are preferably composed of foamed polycarbonate, some other plastic, or metal. The outer walls are designed and/or arranged such that it is generally possible for air to flow into and/or out of the cavity 4 in a lower area. Furthermore, the roof 11 has gill openings 12 which are connected for flow purposes to the cavity 4 such that air can likewise flow out of and/or into the cavity 4 through them. In other embodiments, it is possible to provide for outlet openings to be provided in the upper area of the outer walls 10, instead of the gill openings 12 in the roof 11.

In some embodiments, the housing 1 also has a base (not illustrated) on which the frame 5 can be mounted and is preferably entirely or partially buried in the ground 9. A power supply, for example in the form of a battery, for supplying electrical power to the electrical devices in the functional area, is frequently arranged in the base.

In the illustrated state, the housing 1 has no rear outer wall in FIG. 1 and no side outer wall in FIG. 2. To a person skilled in the art, it is self-evident that the inner housing 2 as well as the outer housing 3 may each also have a door to allow easy access to the functional area.

The side walls 6 of the inner housing 2 are metal sheets which are shaped with structuring 13 at least in an area which seals the functional area. The structuring is shaped to make the surface area of the metal sheet greater than that of a planar, smooth, flat metal sheet. In the illustrated embodiment, the side walls, including any door which may be provided for the functional area, are structured periodically in a corrugated form, preferably sinusoidally, so as to create channels 14 which run in straight lines. These preferably extend at an angle of less than ±45° to a vertical, and most preferably parallel to the vertical. This assists optimum flow formation both in the interior of the functional area and in the cavity 4. The structures on the side walls 6 in FIG. 1 and on the front and rear side walls 6 in FIG. 2 are not shown, in order to simplify the illustration.

The minimum distance between the side walls 6 and the outer wall 10 in the cavity 4 in the region of the structuring 13 is designed to be matched to the required or desired fluid flow rate through the cavity 4. The less the fluid flow rate, the shorter this minimum distance is chosen to be. Conversely, the minimum distance is chosen to be greater if an increased fluid flow rate is intended, which is assisted and/or maintained by an active element, for example one or more fans. Furthermore, the noise that is created must be taken into account, which can occur in the event of high fluid flow rates on structures which are only a short distance apart from one another. The creation of such noise is undesirable, and should be avoided.

FIG. 3 shows an isometric view of one example of a side wall. The structuring 13 is formed by deep-drawing in the metal sheet which forms a side wall 6 of the inner housing 2. Of the straight-line channels that are formed, only one half is open toward the viewing side 15. All the channels 14 (the channels which are open toward the viewing side as well as the channels which are open toward the opposite side) have the same channel width and the same channel depth. The structuring 13 is periodic. Furthermore, it is designed such that the metal sheets can be stacked. In this case, the surface pointing toward the viewing side is designed to be complementary to the opposite surface so that the structuring engages in the structuring on the sheet located below when stacking, or vice versa. In the illustrated embodiment, the side wall 6 (the metal sheet) has a circumferential smooth and flat rim 22. The rim 22 makes it easier to seal the functional area and to attach the side wall 6 to the frame 5.

In order to assist clarity, FIG. 4a shows a contour 16 which is in the form of a section line through the metal sheet and the structuring 13 on a plane which is oriented at right angles to the straight-line profile of the channels 14 and the area extent of the metal sheet.

This clearly shows that the contour in the region of the structuring 13 is periodic. The period length 17 of the structuring in the preferred embodiment is equal to the structure depth 18. In this embodiment, the period length is identical to the maximum channel width 19. Corrugated or sinusoidal structuring has the advantage that radiated heat emissions at right angles to the surface of the metal sheet 20, as is indicated by the arrows 21, are not directed directly back to the metal sheet 20. This improves the heat transfer in comparison to other embodiments which are shown in FIGS. 4b, 4c and 4e.

In the embodiments illustrated in FIGS. 4b and 4c which, in addition to deep drawing, may, for example, also be shaped simply by bending the metal sheet 20, and have a rectangular profile or a rectangular contour 16 as the section line. The ratio of the period length 17 to the structure depth/channel depth 18 is in this case 4 to 3 (FIGS. 4b) or 2 to 1 (FIG. 4c). In this case, the ratio of the channel width 19 to the structure depth/channel depth 18 is 2 to 3 (FIGS. 4b) or 1 to 1 (FIG. 4c). Other embodiments may have a ratio of the channel width to the channel depth of 1 to 3.

FIG. 4d shows an embodiment with trapezoidal channel cross sections. This offers the advantage that the metal sheets 20 can be stacked better. FIG. 4e shows an embodiment of a rectangular periodic profile, in which all the channels 14 have the same channel depth 18. Adjacent channels each have different channel widths 19, 19′. The difference between the channel widths 19, 19′ is approximately twice the metal-sheet thickness 21. The metal sheets 20 can also be stacked in an embodiment such as this.

As is evident to a person skilled in the art, embodiments have been described only by way of example. The individual features of the various embodiments may be used individually or combined in order to implement the invention.

### REFERENCE SYMBOLS

1 Housing

2 Inner housing

3 Outer housing

4 Cavity

5 Frame

6 Side walls

7 Top

8 Bottom

9 Ground

10 Outer walls

11 Roof

12 Gill openings

13 Structuring

14 Channels

15 Viewing side

16 Contour (section line)

17 Period length

18 Structure depth (channel depth)

19, 19′ Channel width

20 Metal sheet

21 Arrows

22 Rim

1. A housing for installation in the open air in order to accommodate electrical devices, in particular components for communication and/or data technology, comprising an inner housing in which a hermetically sealed functional area is provided for accommodation of the electrical devices, and an outer housing, which is arranged around the inner housing in such a way that a cavity is formed between the inner housing and the outer housing, with side walls of the inner housing also being the side walls of the functional area, wherein the side walls of the inner housing are metal sheets, with at least one of the metal sheets being shaped with structuring such that the area in the region of the structuring is greater than that of a smooth, flat surface.

2. The housing as claimed in claim 1, wherein the structuring is designed such that channels which run in straight lines are formed both on the side facing the functional area and on the side facing the cavity.

3. The housing as claimed in claim 2, wherein the channels are aligned in straight lines at an angle of less than 45° to a vertical, preferably parallel to the vertical.

4. The housing as claimed in claim 3, wherein a section line of the structuring forms a periodic contour with a plane at right angles to the straight-line profile of the channels.

5. The housing as claimed in claim 4, wherein the periodic contour has a rectangular, triangular, trapezoidal, corrugated or sinusoidal shape, or a shape similar to a sinusoid.

6. The housing as claimed in claim 5, wherein the ratio of the period length to the structure depth is between 3 to 1 and 1 to 4, preferably between 2 to 1 and 2 to 3.
